(19) United States
(12) Patent Application Publication
(10) Pub. No.: US 2005/0128108 A1
(43) Pub. Date: Jun. 16, 2005

(54) Keyboard with translator function

(76) Inventor: Ching-Shi Fong, Taipei (TW)

Correspondence Address: Ching-Shi Fong, PO Box 82-144, Taipei, TW

(21) Appl. No.: 10/735,921

(22) Filed: Dec. 16, 2003

(51) Int. Cl. H03M 11/00; H03K 17/94

(52) U.S. Cl. 341/22

(57) ABSTRACT

A keyboard with functions of a translator, essentially comprised of a microprocessor containing translation software being provided in the keyboard, the microprocessor being connected to an LCD; existing keys on the keyboard and additional keys; words pending translation being entered for those translation software to display the translation results on the LCD; and the microprocessor being also connected to a speaker and a memory expansion slot for delivering the pronunciation of the translated word allowing external connection to the memory to enhance practical value of the keyboard.

### BACKGROUND OF THE INVENTION

(a) Technical Field of the Invention

The present invention is related to a keyboard provide with functions of a translator, and more particularly, those existing keys of the keyboard also are given with functions of the translator.

(b) Description of the Prior Art

Whereas a translator generally available in the market is generally used for the translation between two different languages, the translator is portable but fails an affordable price. Furthermore, the adaptation of the translator to the computer is not so convenient and it will affect the efficiency of the computer operation since the computer practically executes all the existing documentation work. Even though there is translation software available for installation in the computer, the computer must be started to allow access to those software. Therefore, the translation operation is prevented once the computer is shut off.

### SUMMARY OF THE INVENTION

The primary purpose of the present invention is to provide a keyboard with functions of a translator for the keyboard to execute functions of the translator by pressing on the existing keys without the necessity to provide additional keys.

To achieve the purpose, a microprocessor installed with translation software is provided in the keyboard. The microprocessor is connected to an LCD provided on the upper part of the surface of the keyboard. Additional special keys are provided to enter the word pending translation. The translation software is executed to display the results of the translation on the LCD.

The microprocessor is also connected to a phonetic circuit and a speaker to pronounce the translated word for A/V learning results.

The microprocessor is further connected to a memory expansion slot for external connection to a memory for enhanced practical value of the keyboard of the present invention.

The entire keyboard circuit of the present invention is connected to a built-in battery or an external source for the keyboard to independently execute its translation function whenever the computer is shut down.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of a preferred embodiment of the present invention.

FIG. 2 is an exploded view of the present invention of the present invention.

FIG. 3 is a circuit block chart of the preferred embodiment of the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

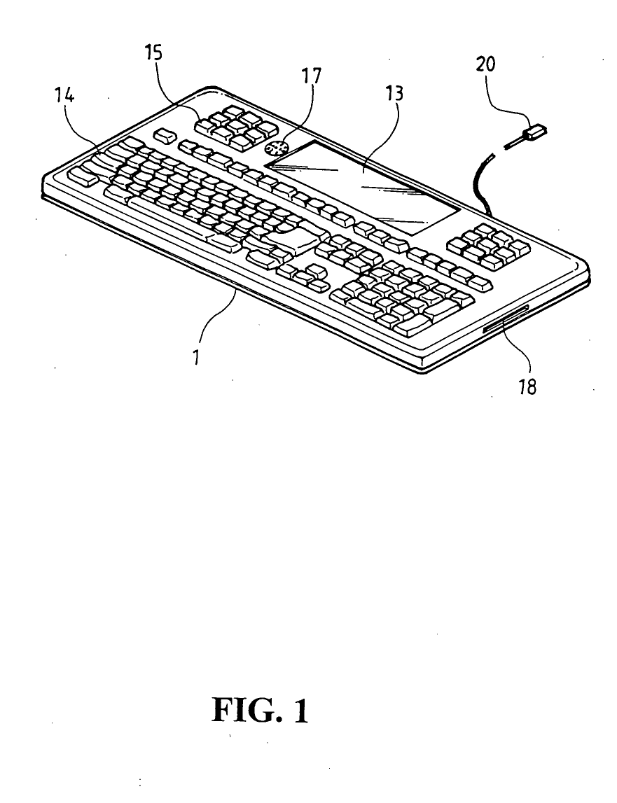

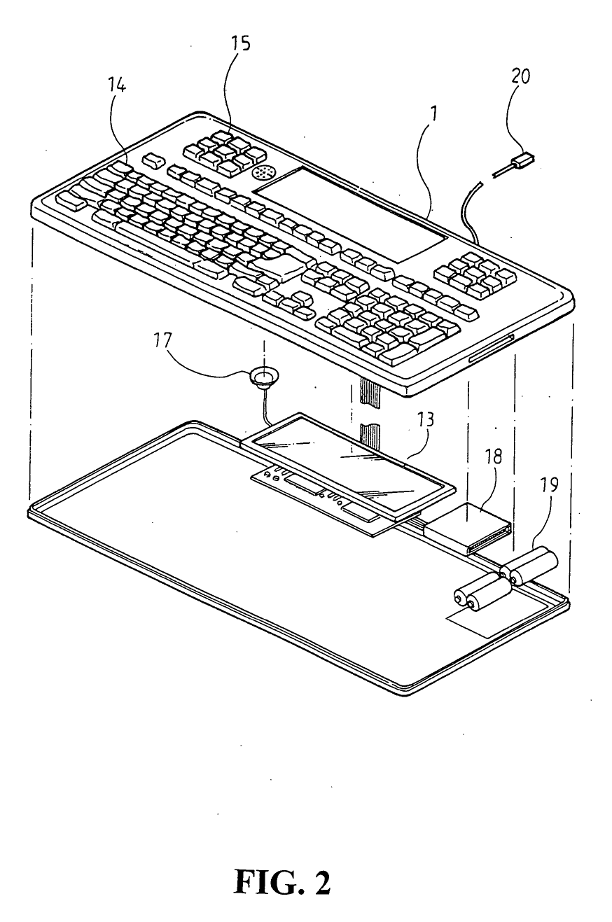

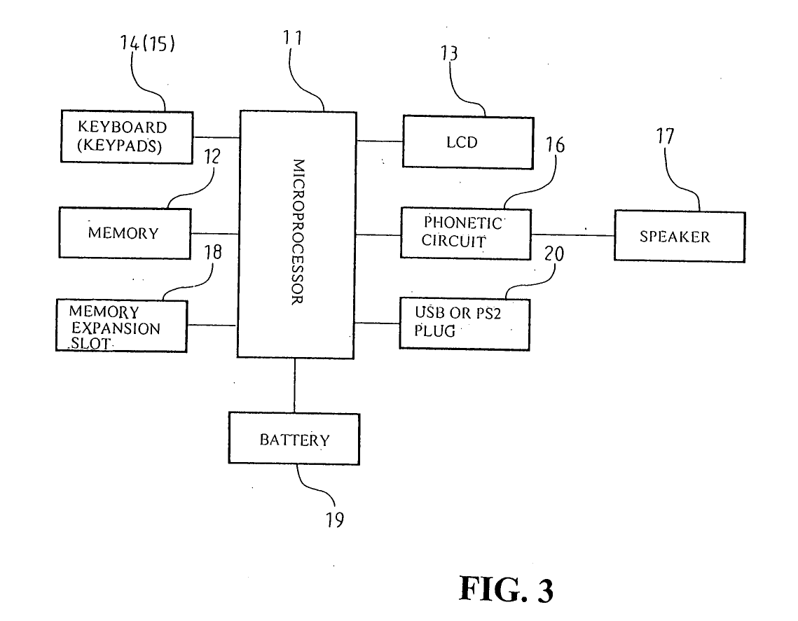

Referring to FIGS. 1, 2, and 3, a preferred embodiment of the present invention is essentially comprised of a microprocessor 11 provided on a keyboard 1 (the size of the keyboard is larger than that of the prior art). The microprocessor 11 is connected to a memory 12, and is provided with keyboard and translation software.

The microprocessor 11 is connected to a LCD 13 provided on the upper part of the surface of the keyboard 1, and is also connected to those existing keys, i.e., those numeric, letter and symbol keys, and two special keypads 15 respectively provided on both sides of the LCD 13.

The microprocessor 11 is further connected to a phonetic circuit 16, a speaker 17 and a memory expansion slot 18. The microprocessor 11 and the circuit to its peripheral are connected to a battery 19 or an external source of a power transformer.

When assembled, the keyboard 1 is plugged to the computer with a USB or a PS2 plug so to operate the computer by those keys 14 as usual. When a translation task is desired, the translation function is enabled to enter the word by pressing those keys 14 in conjunction with the setup of those keypads 15 and the word as translated is displayed on the LCD 13.

In the course of performing the translation task, the microprocessor 11 sounds the correct pronunciation of the world translated by the phonetic circuit 16 and through the speaker 17 for the user to visual the word as translated while listing to its pronunciation.

Whereas it is not necessary to use the computer for the translation take, the computer can be shut off. By having the entire circuit of the preferred embodiment connected to the battery 19 or the external source (e.g., a source transformer) for the battery 19 or the external source to supply the power needed by the work of the keyboard 1. The keyboard 1 therefore is able to perform the translation task independently. Meanwhile, the memory expansion slot 18 is provided for connecting to an external memory for extending the data installed in the keyboard to give additional effects to the translation task for improved the practical value of the preferred embodiment of the present invention.

Additional applications including notebook, phone directory and game functions may be further installed in the microprocessor 11 to perform those additional functions by punching those keys 14 and/or special keypads 15.

The present invention by providing translation function to the keyboard with or without connecting the keyboard to the computer is related to an innovative and practical design. Therefore, this application for a utility patent is duly filed accordingly.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spit of the present invention.

1. A keyboard with functions of a translator is comprised of a microprocessor containing translation software connected to a LCD provided on the upper part on the surface of the keyboard; the word pending translation being entered by pressing the keys on the keyboard, then processed by the translation software to display the word translated on the LCD.

2. A keyboard with functions of a translator as claimed in claim 1, wherein, the microprocessor is connected to a speaker through a phonetic circuit to sound the correct pronunciation of the translated word.

3. A keyboard with functions of a translator as claimed in claim 1, wherein, the microprocessor and its peripheral circuit are connected to a battery built in the keyboard or to an external source for the keyboard to independently exercise its translation function when the computer is shut off.
